(19) United States
(12) Patent Application Publication
(10) Pub. No.: US 2021/0396219 A1
(43) Pub. Date: Dec. 23, 2021

(54) METHOD OF CONTROLLING A VOLUME WHICH CAN BE CONVEYED WITH A METERING PUMP

(71) Applicant: ProMinent GmbH, Heidelberg (DE)

(72) Inventor: Martin Reinhard, Heidelberg (DE)

(21) Appl. No.: 17/341,586

(22) Filed: Jun. 8, 2021

(30) Foreign Application Priority Data
Jun. 18, 2020 (DE) 10 2020 116 071.2

(51) Int. Cl. F04B 13/00; F04B 49/00; G06F 7/556

(52) U.S. Cl. CPC F04B 13/00; H03M 1/12; G06F 7/556; F04B 49/00

(57) ABSTRACT

The present invention concerns a method of controlling a liquid volume which can be conveyed with a metering pump in a given time, comprising the steps: a. providing an input signal for controlling the liquid volume which can be conveyed with the metering pump in the given time, and b.lLinking the input signal to an actuating signal which influences the liquid volume which can be conveyed with the metering pump in the given time so that a change in the input signal leads to a change in the actuating signal and thus a change in the liquid volume which can be conveyed. To react to individual process demands it is proposed according to the invention that linking in step b. is effected in such a way that a change in the input signal leads to a change in the liquid volume which can be conveyed with the metering pump in the given time, which change in the liquid volume is non-proportional to the change in the input signal.

The present invention concerns a method of controlling a liquid volume which can be conveyed with a metering pump in a given time, comprising the steps:

a. providing an input signal for controlling the liquid volume which can be conveyed with the metering pump in the given time, and

b. linking the input signal to an actuating signal which influences the liquid volume which can be conveyed with the metering pump in the given time so that a change in the input signal leads to a change in the actuating signal and thus a change in the liquid volume which can be conveyed with the metering pump in the given time.

In addition the invention concerns A metering pump for conveying a liquid volume of a liquid in a given time, comprising a metering chamber, a displacement element moveable between a first and a second position, wherein the displacement element is so connected to the metering chamber that a metering chamber volume of the metering chamber is varied with the movement of the displacement element between the first and second positions, a drive for moving the displacement element between the first and the second position, and a control, wherein the control is so connected to the drive that during operation of the metering pump the drive is controlled by means of the actuating signal by the control so that the liquid volume of the liquid which is conveyed by the metering pump in the given time is varied by a change in the actuating signal, wherein the control further has an input for an input signal, wherein the input signal at the input is linked in the control to the actuating signal so that a change in the input signal links to a change in the actuating signal.

Metering pumps are used in the most widely varying areas of application. They are used for example in metering medicaments or chemicals in chemical processes, for metering culture media in biotechnical processes, in coating methods, in the foodstuffs industry or in motor vehicles for example as injection pumps. The possible uses of metering pumps are many and varied and accordingly the demands made on the metering pumps in industry are also many and varied.

In principle metering pumps are displacement pumps which convey defined volumes of liquid per revolution, stroke or time independently of the pressure conditions at theft inlet and outlet. The metering operation is effected in the case of a metering pump by displacement of a closed chamber volume by means of a displacement element. The liquid volume conveyed by the metering pump per revolution, stroke or time ensues from the product of the stroke and the effective area of the displacement element.

The liquid volume which is conveyed by the metering pump in a given time can in that case be influenced on the one hand for example by the size of the metering chamber of the metering pump or on the other hand by the stroke frequency or stroke speed of the metering pump.

In metering pumps the generally continuous rotary movement of a drive is frequently converted by a transmission unit into an oscillating movement of the displacement element. Accordingly the stroke frequency of the metering pump and therewith in turn the liquid volume which can be conveyed by the metering pump can be varied by suitable actuation of the drive.

It is known from the state of the art in this connection that to control the metering pump, there is provided an input signal which is converted into an actuating signal for the drive by a control system of the metering pump. In that case conversion of the input signal is effected in such a way that a change in the liquid volume which can be conveyed by the metering pump is proportional to a change in the input signal. Thus, depending on the respectively applied input signal, more or less liquid is conveyed by the metering pump.

In addition it is known for any non-proportionality between the change in the liquid volume which can be conveyed by the metering pump and the input signal, for example due to environmental influences or wear in the components of the metering pump, to be compensated by a suitable control system in such a way that a proportionality between the specified variables is restored. In that case it may be necessary to produce a non-proportional relationship between the input signal and the actuating signal so that the input signal and the liquid volume conveyed in a given time are again proportional to each other. A change in the input signal to a given degree however always results in a change in the liquid volume which can be conveyed in a given time, to the same degree.

As mentioned in the introductory part of this specification it is however frequently desired for the liquid volume which can be conveyed with the metering pump to be more individually adapted to the respective requirements of a process in dependence on time. Thus for example in the area of a liquid volume which can be optimally conveyed per time for a process a particularly short-step adjustment of the liquid volume which can be conveyed is frequently wanted, whereas in other areas the change can be effected in coarser steps. That however is not possible with a proportional relationship between the input signal and a liquid volume which can be conveyed in a given time.

Taking the described state of the art as the starting point the object of the present invention is to provide a method of controlling a liquid volume which can be conveyed with a metering pump in a given time, with which it is possible to react to individual process demands. In addition an object of the invention is to provide a metering pump whose liquid volume which can be conveyed in a given time can be individually adapted to process requirements.

That object is attained by a method of controlling a liquid volume which can be conveyed with a metering pump in a given time, comprising the steps:

a. providing an input signal for controlling the liquid volume which can be conveyed with the metering pump in the given time, and

b. linking the input signal to an actuating signal which influences the liquid volume which can be conveyed with the metering pump in the given time so that a change in the input signal leads to a change in the actuating signal and thus a change in the liquid volume which can be conveyed with the metering pump in the given time, wherein linking in step b. is effected in such a way that a change in the input signal leads to a change in the liquid volume which can be conveyed with the metering pump in the given time, which change in the liquid volume is non-proportional to the change in the input signal.

The input signal can be a digital or analog signal which is frequently afforded on the part of the user of a metering pump. Inexpensive electronic components which permit a change in the input signal are available for generating such an input signal. In that respect a value range in which the values of the input signal may move is predetermined for the input signal. For example the method can be provided for input voltage signals between 0 V and 15 V.

The non-proportional linking between the input signal and the actuating signal according to the invention has the result that the liquid volume which can be conveyed with the metering pump in a given time changes non-proportionally to the input signal. Accordingly the method according to the invention differs from the state of the art in that there is not a proportional relationship between the input signal and the liquid volume which can be conveyed with the metering pump in a given time.

The term proportional relationship is used in accordance with the invention to mean that the input signal and the liquid volume which can be conveyed with the metering pump in a given time are always in the same relationship with each other, that is to say the one variable transitions into the other variable by multiplication with a constant proportionality factor. If therefore reference is made in accordance with the invention to a non-proportional relationship, this means a relationship in which the two specified variables cannot be converted into each other by multiplication with a constant proportionality factor. Mathematically that relationship can be expressed as follows:

y(x)=m(x)^{a}+c(x)

with y being the liquid volume which can be conveyed, x being the input signal and m being the constant proportionality factor. c(x) is a variable which is dependent on the input signal and which can assume any function. In the simplest case c(x)=0. In addition in accordance with the invention only those relationships in which α≠1 are viewed as non-proportional.

The method according to the invention therefore aims to produce a deliberate non-proportionality between input signal and liquid volume which can be conveyed. The non-proportionality between the input signal and the actuating signal therefore does not have the aim, as in the state of the art, of compensating for any deviations from a proportional linking for example due to environmental influences or wear, which ultimately leads again to a proportional relationship between the input signal and the liquid volume which can be conveyed, but the non-proportional linking between the input signal and the actuating signal is so effected that the input signal and the liquid volume which can be conveyed are also non-proportionally linked to each other.

The method according to the invention thus affords the advantage that an input signal which is present for example on the part of the user of the metering pump is individually adapted to the respective process requirements. In addition with one and the same input signal, it is possible to achieve a different delivery volume on the part of the metering pump, depending on the respective design configuration of the control.

Thus it may be possible that at the beginning of a process more liquid is to be introduced into a mixture than towards the end a process at which a proportion of the liquid is to be set as precisely as possible. Here the method according to the invention affords the advantage that for example at the beginning of the process the input signal leads to a rapid change in the liquid volume which can be conveyed whereas towards the end of the process or shortly before approaching an optimum liquid volume per time finer matching of the change in the liquid volume is possible on the basis of the input signal. Thus on the one hand this permits a time saving at the beginning of the process while on the other hand it affords more accurate setting of the desired supply of liquid which ultimately results in the products manufactured being of higher quality.

In a further embodiment linking in step b. is effected in such a way that a change in the input signal leads to a change in the liquid volume which can be conveyed with the metering pump in the given time, said change in the liquid volume being non-linear in relation to the change in the input signal. That is to say in this case even relationships between input signal and actuating signal or liquid volume which can be conveyed in accordance with

y(x)=mx+b

are excluded, wherein b is the shift constant of a linear function.

Linking of the input signal to the actuating signal can be effected in various ways. In an embodiment a data set in which a value of the actuating signal is previously already allocated to each input signal is set up for linking the input signal to the actuating signal. That gives the advantage of saving on computing capacities in the control system while control of the metering pump can be very individually adapted to the process requirements. Setting up a data set is appropriate in particular for smaller control ranges which contain only a limited number of values and where it is precisely known what value of the input signal is to be associated to what liquid volume can be conveyed in a given time.

In a further embodiment of the invention linking of the input signal to the actuating signal is effected by way of a mathematical function, wherein the mathematical function is a non-proportional, preferably non-linear function. A mathematical function has the advantage that it is possible to automatically associate with each value of the input signal a corresponding value of the actuating signal. Thus even values of the actuating signal which previously for example have not yet been manually established can be associated with values of the input signal.

In a further embodiment of the method according to the invention the mathematical function is a strictly monotonically increasing or a strictly monotonically falling function. This ensures that there is attributed to each input value an actuating value which is different from the adjacent actuating values so that a change in the input signal also always leads to a change in the liquid volume which can be conveyed with the metering pump in a given time.

In a further embodiment the mathematical function is a polynomial, preferably a polynomial of degree 2 and particularly preferably a polynomial of degree 3. Polynomials can be adapted to almost any function implementation in dependence on their number of the degrees. The use of a polynomial therefore gives the advantage that it is possible to produce a particularly individual control profile for the liquid volume, while at the same time no manual association of the values of the input signal with values of the actuating signal in a stored data set is previously necessary.

In a further embodiment the input signal is an analog signal, preferably a voltage signal, wherein the analog input signal in an additional step is converted into a digital intermediate signal, wherein the digital intermediate signal is linked in step b. to the actuating signal. The digital intermediate signal is thus connected both to the input signal and also the actuating signal. Digital signals can be more easily and also more accurately linked to the actuating signal in the control system.

In a further embodiment the digital intermediate signal has preferably 25 steps. That number of steps is still to be managed in a short time in terms of computing engineering but at the same time also affords sufficiently good resolution to adequately represent a change in the input signal.

In a further embodiment of the method according to the invention in step b. linking is effected in such a way that a linearly increasing input signal firstly leads to an increase in the liquid volume which can be conveyed with the metering pump in the given time and then a drop in the liquid volume which can be conveyed with the metering pump in the given time.

In other words for example a linear increase in the input signal can firstly lead to an increase and thereafter a reduction in the conveyor speed. In that case the gradient of the increase can be less than or greater than the magnitude of the gradient of the reduction.

### EXAMPLE 1

Bandwidth of the input signal: 0-100V
Bandwidth of the conveyor speed: 0-10 l/s
Input signal interval 1: 0-20V Conveyor speed interval 1: 0-10 l/s
Input signal interval 2: 20V-100V Conveyor speed interval 2: 10-8 l/s

With an input signal between 0 and 20V the pump can be actuated between a conveyor speed of 0 and 10 l/s. A voltage change of 0.5 V then leads to a change in the conveyor speed of 0.25 l/s. Accurate metering is thus difficult.

In the input signal interval 2 a further conveyor speed interval is available. With an input signal between 20 and 100V the pump can be actuated between a conveyor speed of 10 and 8 l/s, wherein with a voltage of 100V a conveyor speed of 3 l/s is reached. In the input signal interval a voltage change of 0.5 V leads to a change in the conveyor speed of 0.0125 l/s. Accurate metering is thus much easier.

Such a linking characteristic is meaningful if a conveyor speed of between 8 and 10 ifs is generally wanted.

In a preferred embodiment the mathematical function is selected on the basis of the intended conveyor speeds.

The object of the invention is in addition attained by a metering pump for conveying a liquid volume of a liquid in a given time, wherein the metering pump has a metering chamber, a displacement element moveable between a first and a second position, a drive for moving the displacement element between the first and the second positions and a control, wherein the displacement element is so connected to the metering chamber that a metering chamber volume of the metering chamber is varied with the movement of the displacement element between the first and second positions, wherein the control is so connected to the drive that during operation of the metering pump the drive is controlled by means of the actuating signal by the control, so that the liquid volume of the liquid which is conveyed by the metering pump in the given time is varied by a change in the actuating signal, wherein the control further has an input for an input signal, wherein the input signal at the input is linked in the control to the actuating signal so that a change in the input signal leads to a change in the actuating signal, wherein the input signal is linked to the actuating signal in the control in such a way that a change in the input signal leads to a change in the liquid volume which is conveyed by the metering pump in the given time, said change in the liquid volume being non-proportional to the change in the input signal.

If the method is carried into effect with a metering pump according to this invention it has the appropriate devices for that purpose. In particular embodiments of the metering pump are suitable for carrying out the above-described embodiments of the method.

According to the invention it is therefore provided that an input signal is made available by an external source. The actuating signal is then generated in dependence on the input signal.

In an embodiment the actuating signal influences a stroke frequency, a stroke length and/or a stroke speed of the displacement element of the metering pump. Those three variables of the metering pump have a significant influence on the liquid volume which can be conveyed with the metering pump in a given time.

In a further embodiment the input signal is a digital input signal or the input signal is converted into a digital intermediate signal by means of an analog-digital converter. In addition the actuating signal in this embodiment is an analog signal, wherein the control system of the metering pump further has a digital-analog converter, wherein the digital input signal or the digital intermediate signal is converted into the analog actuating signal in the control system by means of the digital-analog converter, wherein the digital-analog converter is a non-proportional digital-analog converter.

Usually analog-digital converters or digital-analog converters lead to a proportional conversion between input and output signal. Accordingly in accordance with the invention proportional conversion denotes a conversion which always converts the values of the input signal into values of the output signal by a constant proportionality factor. Even if for example an analog-digital converter reduces the values of an input signal to a few values of an output signal those values of the output signal can always still be set in relation to the values of the input signal by a constant proportionality value.

The term non-proportional digital-analog converter is therefore used in accordance with the invention to denote such a digital-analog converter which converts input values of a signal in such a way that they can no longer be related together by way of a common constant proportionality factor.

Further advantages, features and possible uses of the present invention will be apparent from the description hereinafter of an embodiment and the accompanying Figures. Identical components in that case are denoted by the same references.

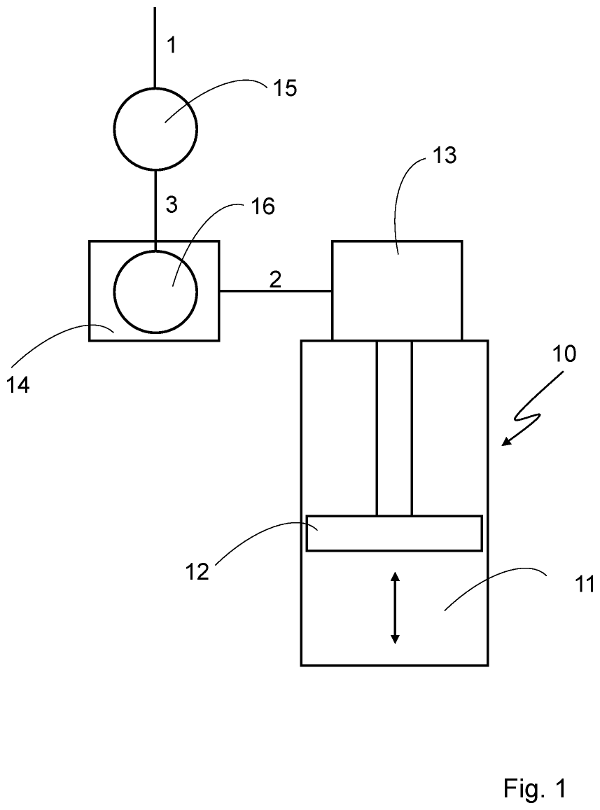

FIG. 1 shows a diagrammatic view of an embodiment of the metering pump according to the invention,

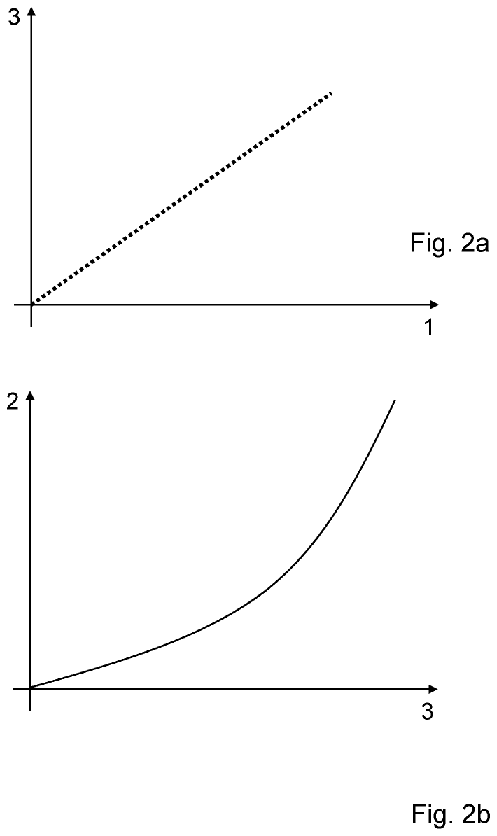

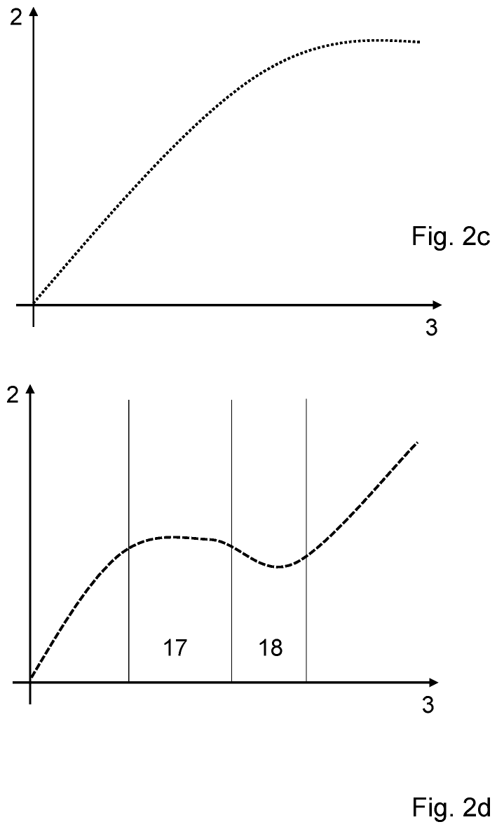

FIG. 2a diagrammatically shows the digital intermediate signal in dependence on the input signal,

FIG. 2b diagrammatically shows the actuating signal in dependence on the digital intermediate signal in a first embodiment of the method according to the invention,

FIG. 2c diagrammatically shows the actuating signal in dependence on the digital intermediate signal in a second embodiment of the method according to the invention, and

FIG. 2d diagrammatically shows the actuating signal in dependence on the digital intermediate signal in a third embodiment of the method according to the invention.

FIG. 1 shows an embodiment of the metering pump 10 according to the invention having a metering chamber 11 and a displacement element 12 moveable between a first and a second position, wherein the displacement element 12 is reciprocated between the first and the second positions by a drive 13. In addition the metering pump 10 according to the invention has a control 14, the control 14 being so connected to the drive 13 that an actuating signal 2 is passed to the drive 13 by the control 14. The control 14 thus controls the drive 13 by means of the actuating signal 2.

Liquid is drawn into or pushed out of the stroke chamber 11 by the movement of the displacement element 12. In that situation the control 14 acts by means of the actuating signal 2 and the drive 13 on the stroke frequency of the displacement element 12 and the metering chamber volume of the metering pump 10. In that way the liquid volume which can be conveyed with the metering pump 10 in the given time can be varied.

The change in the liquid volume which can be conveyed with the metering pump 10 in a given time is implemented by means of an analog input signal 1, like for example a voltage signal which in a first step is converted into a digital intermediate signal 3 by an analog-digital converter 15. That digital intermediate signal can for example assume up to 25 discrete values. The ditial intermediate signal 3 is passed to the control 14 which in turn has a digital-analog converter 16 for converting the digital intermediate signal 3 into the analog actuating signal 2 in such a way that a change in the input signal 1 or the digital intermediate signal 3 leads to a non-proportional change in the actuating signal 2 and thus a non-proportional change in the liquid volume which can be conveyed with the metering pump 10 in a given time.

FIG. 2a shows the result of analog-digital conversion by means of the analog-digital converter 15. It can be seen that the analog-digital converter 15 converts the incoming input signal 1 proportionally into the digital intermediate signal 3, that is to say the values of the input signal 1 are linked to the values of the digital intermediate signal 3 by way of a proportionality factor.

FIG. 2b then shows the result of a first embodiment of the digital-analog converter 16 which links the digital intermediate signal 3 to the actuating signal 2 by way of a non-proportional mathematical function. As shown in FIG. 2 the mathematical function is a square function of the form y=x². A change in the digital intermediate signal 3 or the input signal 1 at low values here results in a comparatively slight change in the actuating signal 3 and thus the liquid volume which can be conveyed with the metering pump 10 in a given time. A change in the ditial input signal 3 at higher values in contrast leads to a more marked change in the actuating signal 2. In this embodiment for example at the beginning of a process initially little liquid can be supplied in very targeted fashion and at a later time more liquid when a less accurate setting of the supply of liquid is adequate.

In FIG. 2c linking of the digital intermediate signal 3 to the actuating signal 2 is effected in the digital-analog converter 16 by way of a root-form function. While at low values of the digital intermediate signal a comparatively great change in the actuating signal 2 and thus also a great change in the liquid volume which can be conveyed with the metering pump 10 in a given time is achieved, a change in the digital intermediate signal 3 at higher values leads to a lesser change in the actuating signal. In this FIG. 2c embodiment therefore it is possible firstly to quickly achieve a desired liquid volume which can then be adjusted in fine steps.

FIG. 2d shows the output of a further embodiment of the digital-analog converter 16. It will be seen that here there is a first sub-interval 17 in the digital intermediate signal, in which a change in the digital intermediate signal 3 leads to no or almost no variation in the actuating signal 2. In a second sub-interval 18 of the digital intermediate signal 3 the actuating signal passes through a minimum.

In the case of such linking of the input signal 1 or the digital intermediate signal 3 to the actuating signal 2 therefore a local maximum is achieved in the first sub-interval 17 and a local minimum in the second sub-interval 18. Those local minima and maxima can be individually adapted to the process requirements.

In contrast to the known systems in the state of the art the conveyor speed can be very accurately set in the desired range with an analog input signal which is easy to generate. The user of the pump does not have to make any high-level demands on the reliability and accuracy of the input signal.

### LIST OF REFERENCES

1 input signal
2 actuating signal
3 intermediate signal
10 metering pump
11 metering chamber
12 displacement element
13 drive
14 control
15 analog-digital converter
16 digital-analog converter
17 first sub-interval
18 second sub-interval

1. A method of controlling a liquid volume which can be conveyed with a metering pump (10) in a given time, comprising the steps:
a. providing an input signal (1) for controlling the liquid volume which can be conveyed with the metering pump (10) in the given time, and
b. linking the input signal (1) to an actuating signal (2) which influences the liquid volume which can be conveyed with the metering pump (10) in the given time so that a change in the input signal (1) leads to a change in the actuating signal (2) and thus a change in the liquid volume which can be conveyed with the metering pump (10) in the given time,
c. characterised in that linking in step b. is effected in such a way that a change in the input signal (1) leads to a change in the liquid volume which can be conveyed with the metering pump (10) in the given time, which change in the liquid volume is non-proportional to the change in the input signal (1).

2. A method according to claim 1 characterised in that linking in step b. is effected in such a way that a change in the input signal (1) leads to a change in the liquid volume which can be conveyed with the metering pump (10) in the given time, said change in the liquid volume being non-linear in relation to the change in the input signal (1).

3. A method according to claim 1 wherein linking of the input signal (1) to the actuating signal (2) is effected by way of a mathematical function, wherein the mathematical function is a non-proportional function.

4. A method according to claim 3 wherein the mathematical function is a strictly monotonically rising or a strictly monotonically falling function.

5. A method according to claim 1 wherein the mathematical function is a polynomial.

6. A method according to claim 1 wherein the input signal (1) is an analog signal wherein the analog input signal (1) in an additional step is converted into a digital intermediate signal (3), wherein the digital intermediate signal (3) is linked in step b. to the actuating signal (2).

7. A method according to claim 1 wherein in step b. linking is effected in such a way that a linearly increasing input signal firstly leads to an increase in the liquid volume which can be conveyed with the metering pump (10) in the given time and then a drop in the liquid volume which can be conveyed with the metering pump (10) in the given time.

8. A metering pump (10) for conveying a liquid volume of a liquid in a given time, comprising
a metering chamber (11),
a displacement element (12) moveable between a first and a second position, wherein the displacement element (12) is so connected to the metering chamber (11) that a metering chamber volume of the metering chamber (11) is varied with the movement of the displacement element (12) between the first and second positions,
a drive (13) for moving the displacement element (12) between the first and the second position, and
a control (14), wherein the control (14) is so connected to the drive (13) that during operation of the metering pump (10) the drive (13) is controlled by means of the actuating signal (2) by the control (14) so that the liquid volume of the liquid which is conveyed by the metering pump (10) in the given time is varied by a change in the actuating signal (2), wherein the control (14) further has an input for an input signal (1), wherein the input signal (1) at the input is linked in the control (14) to the actuating signal (2) so that a change in the input signal (1) leads to a change in the actuating signal (2), characterised in that the input signal (1) is linked to the actuating signal (2) in the control (14) in such a way that a change in the input signal (1) leads to change in the liquid volume conveyed by the metering pump (10) in the given time, said change in the liquid volume being non-proportional to the change in the input signal.

9. A metering pump (10) according to claim 8 wherein the actuating signal influences a stroke frequency, a stroke length and/or a stroke speed of the displacement element (12) of the metering pump (10).

10. A metering pump (10) according to claim 8 wherein the input signal (1) is a digital input signal (1) or is converted by means of an analog-digital converter (15) into a digital intermediate signal (3), wherein the actuating signal (2) is an analog signal, wherein the control (14) of the metering pump (10) further has a digital-analog converter (16), wherein the digital input signal (1) or the digital intermediate signal (3) is converted into the analog actuating signal (2) in the control (14) by means of the digital-analog converter (16), wherein the digital-analog converter (16) is a non-proportional digital-analog converter (16).

11. A method according to claim 3 wherein the mathematical function is a non-linear function.

12. A method according to claim 5 wherein the mathematical function is a polynomial of degree 2.

13. A method according to claim 5 wherein the mathematical function is a polynomial of degree 3.

14. A method according to claim 6 wherein the analog signal is a voltage.
